(19) United States
(12) Patent Application Publication
(10) Pub. No.: US 2026/0313827 A1
(43) Pub. Date: Oct. 8, 2026

(54) AUTOMATIC SLOT IDENTIFIER DETECTION AND MANAGEMENT FOR RACK SYSTEMS

(71) Applicant: Quanta Computer Inc., Taoyuan City (TW)

(72) Inventors: Chun-Chia SU, Taoyuan City (TW); Ying-Huan CHEN, Taoyuan City (TW); Wei-Tsung TANG, Taoyuan City (TW); Yangtzu LEE, Taoyuan City (TW)

(21) Appl. No.: 19/222,110

(22) Filed: May 29, 2025

Related U.S. Application Data
(60) Provisional application No. 63/783,033, filed on Apr. 3, 2025.

(51) Int. Cl. H05K 7/14; H04B 10/114

(52) U.S. Cl. CPC H05K 7/1498; H04B 10/114; H05K 7/1489

(57) ABSTRACT

A computing system includes a server rack and a compute tray. The server rack has an insertion slot that contains a surface pattern and is associated with a slot identifier. The surface pattern has multiple discrete surfaces. The compute tray is insertable into the insertion slot and includes a first group of light transmitters and a respective second group of light receivers. Each of the first group of light transmitters outputs emitted light toward a respective discrete surface of the surface pattern upon insertion of the compute tray. Each of the respective second group of light receivers detects reflected light from the respective discrete surface. The processor is communicatively coupled with the respective second group of light receivers. The second group of light receivers is configured to receive a respective group of signals indicative of the reflected light from the respective second group of light receivers, and determines the slot identifier based on the respective group of signals.

### FIELD OF THE INVENTION

The present invention relates generally to a system and method for detecting and managing the slot identifiers of insertion slots of a server rack. More specifically, the present invention relates to a system and method that detects the slot identifier for an insertion slot into which a compute tray is inserted, and then updates an inventory of compute trays and their operational positions within the server rack.

### BACKGROUND OF THE INVENTION

In traditional high-density server architectures, a backplane or midplane is often used for power distribution and signal routing, including identification of insertion slots. However, backplanes significantly increase mechanical complexity, production costs, and maintenance challenges. Modifications to a backplane-based server rack can be difficult to implement once the system is in place. Replacing or upgrading components often requires intricate procedures. A need exists for automatic slot ID detection and management in server racks without the use of a dedicated backplane.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system for identifying a slot in a server rack includes a server rack and a compute tray. The server rack has an insertion slot with a surface pattern. The insertion slot is associated with a slot identifier. The surface pattern has multiple discrete surfaces. The compute tray is insertable into the insertion slot. The compute tray includes a first group of light transmitters and a respective second group of light receivers. Each of the first group of light transmitters outputs emitted light toward a respective discrete surface of the surface pattern. The emitted light is outputted upon insertion of the compute tray into the insertion slot. Each of the respective second group of light receivers detects, based on the emitted light, reflected light from the respective discrete surface of the surface pattern. A processor is communicatively coupled with the respective second group of light receivers. The processor is configured to receive a group of signals indicative of the reflected light from the second group of light receivers. The processor is also configured to determine the slot identifier based on the group of signals.

According to certain aspects of the present disclosure, each of the plurality of discrete surfaces is a reflective surface or a non-reflective surface.

According to certain aspects of the present disclosure, the reflected light from the discrete surfaces of the surface pattern includes a reflected pattern that corresponds to the surface pattern. The reflected pattern includes an illuminated spot corresponding to each reflective surface and a non-illuminated spot corresponding to each non-reflective surface.

According to certain aspects of the present disclosure, the reflected pattern is representative of a binary number. The respective group of signals includes a one for each illuminated spot and a zero for each non-illuminated spot.

According to certain aspects of the present disclosure, the binary number is a five-bit binary number.

According to certain aspects of the present disclosure, the system further includes a rack management controller communicatively coupled with the processor. The system also includes a network management controller communicatively coupled with the processor. The processor is configured to decode the binary number from the reflected pattern. The processor is also configured to convert the binary number to a decimal number, and assign the decimal value to be the slot identifier. The processor is configured to communicate the slot identifier to the rack management controller and the network management controller.

According to certain aspects of the present disclosure, the server rack has multiple insertion slots. Each of the multiple insertion slots is associated with a respective slot identifier. The slot identifier for each of the multiple insertion slots is unique within the server rack.

According to certain aspects of the present disclosure, a computing system for identifying a slot in a server rack includes a server rack and a compute tray. The server rack has multiple insertion slots. Each slot of the multiple insertion slots has a surface pattern. The surface pattern has a plurality of discrete surfaces. The compute tray is configured for insertion into one of the multiple insertion slots. The compute tray has a group of photosensor modules that align with the surface pattern when the compute tray is inserted into the insertion slot. Each photosensor module includes a light transmitter positioned to transmit an emitted light toward a discrete surface of the surface pattern when the compute tray is inserted in the insertion slot. Each photosensor module also includes a light receiver positioned to receive reflected light from the discrete surface of the surface pattern. A processor is in communication with the group of photosensor modules. The processor is configured to receive a group of signals indicative of the reflected light from the group of photosensors. The processor is also configured to determine a slot identifier based on the group of signals.

According to certain aspects of the present disclosure, the surface pattern for each of the plurality of insertion slots is unique within the server rack.

According to certain aspects of the present disclosure, the light transmitter of each of the group of photosensor modules continues to transmit the emitted light toward the surface pattern as long as the compute tray remains inserted in the insertion slot.

According to certain aspects of the present disclosure, the surface pattern includes one or more reflective surfaces or non-reflective surfaces. Each of the reflective surfaces includes a reflective film applied to a surface of the insertion slot. Each of the non-reflective surfaces includes an absorptive film applied to the surface of the insertion slot.

According to certain aspects of the present disclosure, the emitted light has a wavelength in a range between about 900 nanometers and about 980 nanometers.

According to certain aspects of the present disclosure, the system also includes a rack management controller communicatively coupled with the processor, and a network management controller communicatively coupled with the processor. The processor is also configured to decode the group of signals indicative of the reflected light to be a binary pattern representative of a binary number. The processor is configured to convert the binary number to a decimal number, and assign the decimal value to be the slot identifier. The processor is also configured to communicate the slot identifier to the rack management controller and the network management controller.

According to certain aspects of the present disclosure, a method for automatic slot identifier detection and management of a compute tray in a rack system includes receiving a compute tray into an insertion slot of the server rack. The compute tray has a first group of light transmitters and a respective second group of light receivers. The insertion slot has a surface pattern and is associated with a slot identifier. The surface pattern has multiple discrete surfaces. The method further includes outputting an emitted light from each of the first group of light transmitters when the compute tray is received into the insertion slot. The emitted light is outputted toward a discrete surface of the surface pattern. The method further includes receiving a reflected light from the discrete surface of the surface pattern. The reflected light is received by each of the second group of light receivers on the compute tray. The method further includes receiving a respective group of signals indicative of the reflected light at a processor communicatively coupled with the second group of light receivers. The method further includes determining the slot identifier via the processor and the respective group of signals.

According to certain aspects of the present disclosure, each of the multiple discrete surfaces is a reflective surface or a non-reflective surface. The reflected light from the discrete surfaces of the surface pattern includes a reflected pattern that corresponds to the surface pattern. The reflected pattern includes an illuminated spot corresponding to each reflective surface and a non-illuminated spot corresponding to each non-reflective surface.

According to certain aspects of the present disclosure, the surface pattern has at least five surfaces.

According to certain aspects of the present disclosure, the reflected pattern is representative of a binary number. The respective group of signals includes a one for each illuminated spot and a zero for each non-illuminated spot.

According to certain aspects of the present disclosure, the method further includes the processor decoding the binary number from the group of signals. The method further includes the processor converting the binary number to a decimal number, and assigning the decimal number to be the slot identifier. The method further includes communicating the slot identifier to a rack management controller and a network management controller.

According to certain aspects of the present disclosure, each of the first group of light transmitters continues outputting the emitted light from the transmitter as long as the compute tray remains inserted in the insertion slot.

According to certain aspects of the present disclosure, the emitted light has a wavelength in a range between about 900 nanometers and about 980 nanometers.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a schematic diagram of an exemplary insertion slot identifier detection and management system for a server rack, according to certain aspects of the present disclosure.

FIG. 2 is a schematic diagram of an exemplary compute tray in an uninserted position, according to certain aspects of the present disclosure.

FIG. 3 is a schematic diagram of an exemplary server rack empty of compute trays, according to certain aspects of the present disclosure.

FIG. 4 shows steps of an exemplary method for automatically detecting and managing the slot identifiers in a server rack, according to certain aspects of the present disclosure.

### DETAILED DESCRIPTION

The current invention is a system and method for automatically detecting a slot identifier associated with an insertion slot of a server rack when a compute tray is inserted into the insertion slot. Multiple photosensor modules on the compute tray emit light toward a surface pattern on an inside surface of the insertion slot. The surface pattern has multiple discrete surfaces that encode a binary number indicative of a slot identifier for the insertion slot. Light reflected from the surface pattern is received by the photosensor modules as a reflected pattern of illuminated and non-illuminated spots. The photosensor modules transmit the reflected pattern as binary electrical signals to a processor. The processor decodes the binary number representative of the slot identifier, and communicates the slot identifier to a rack management controller. The rack management controller dynamically updates an inventory and operational mapping of compute trays in the server rack based on the received slot identifier.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

To solve the problems associated with backplanes used in conventional high-density server architectures, the present disclosure offers a system and method that removes the reliance on backplanes for slot ID identification. The disclosed system and method reduces overall cost and complexity. Each compute tray is equipped with photosensor modules (light transmitters and receivers). The photosensor modules detect unique reflective or non-reflective patterns placed in the server rack inside every insertion slot. This system and method automatically assigns a digital ID to an inserted compute tray, ensuring accurate slot identification without the hardware overhead of a backplane. This system and method thus eliminates the need for electrical slot identifier connections and complex wiring through the backplane. Compared to traditional solutions, this photosensor-based system and method offers improved modularity, simpler hardware integration, and greater flexibility for system upgrades or tray replacements.

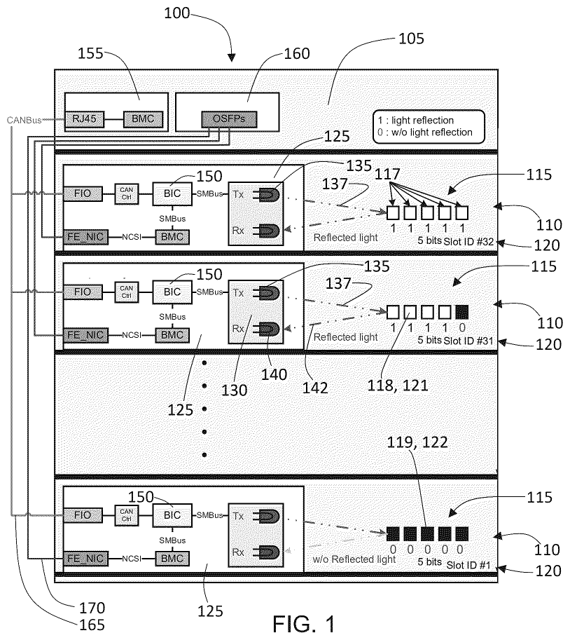

Referring to FIG. 1, an embodiment of a computing system 100 is schematically illustrated. A server rack 105 is shown in a cross-sectional view that illustrates an inside of the server rack 105. The server rack 105 has multiple insertion slots 110. In this example there are 32 insertion slots 110. In other examples, there can be more or less than 32 insertion slots 110. Each insertion slot 110 includes a surface pattern 115 on an inside wall of the insertion slot 110. Each surface pattern 115 is associated with a slot identifier 120. The slot identifier 120 for each of the insertion slots 110 is unique within the server rack 105.

As shown in FIG. 1, each surface pattern 115 has multiple discrete surfaces 117. Each of the discrete surfaces 117 is either a reflective surface 118 or a non-reflective surface 119. In an embodiment, each of the reflective surfaces 118 includes a reflective film 121 applied to the surface of the insertion slot 110. In FIG. 1, the reflective film 121 is indicated as a white square. In an embodiment, each of the non-reflective surfaces 119 includes an absorptive film 122 applied to the surface of the insertion slot 110. In FIG. 1, the absorptive film 122 is indicated as a black square.

A compute tray 125 is insertable into each of the multiple insertion slots 110. The compute tray 125 has multiple photosensor modules 130 that align with the surface pattern 115 when the compute tray is inserted into one of the insertion slots 110. Although FIG. 1 shows a single photosensor module 130 on each compute tray 125 for clarity, there are actual multiple independent photosensor modules 130 on each compute tray 125. There are as many photosensor modules 130 as there are discrete surfaces 117 in the surface pattern 115.

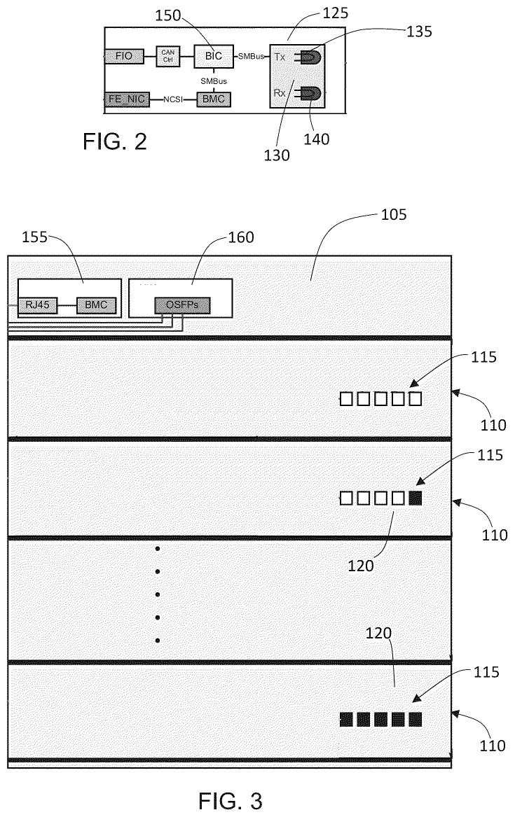

Referring briefly to FIG. 2, a compute tray 125 is shown in a non-inserted position outside of the server rack 105. Referring briefly to FIG. 3, the server rack 105 is shown with all of the compute trays 125 removed. Referring to FIGS. 1 and 2, each compute tray 125 is movable between a non-inserted position (see FIG. 2) and an inserted position (see FIG. 1) relative to an insertion slot 110.

Each photosensor module 130 includes a light transmitter 135. When the compute tray 125 is inserted into the insertion slot 110, the light transmitter 135 transmits an emitted light 137. When the compute tray 125 is inserted into the insertion slot 110, the light transmitter 135 is positioned so that the emitted light 137 is directed toward one of the discrete surfaces 117 of the surface pattern 115. Each photosensor module 130 includes a light receiver 140 corresponding to a light transmitter 135, and is positioned on the compute tray 125. In an embodiment, the emitted light 137 has a wavelength in a range between about 900 nanometers and about 980 nanometers. In another embodiment, the emitted light 137 has a wavelength of about 940 nanometers.

When the compute tray 125 is inserted into the insertion slot 110, the light receiver 140 aligns to receive reflected light 142 from the same one of the discrete surfaces 117 of the surface pattern 115 illuminated by the corresponding light transmitter 135. Each photosensor module 130 therefore acts independently to determine whether the discrete surface 117 with which it is aligned is a reflective surface 118 or a non-reflective surface 119.

The multiple photosensor modules 130 on each compute tray 125 collectively illuminate and receive reflected light 142 from the multiple discrete surfaces 117 of the surface pattern 115. The reflected light 142 received by the light receivers 140 from the discrete surfaces 117 of the surface pattern 115 includes a reflected pattern that corresponds to the surface pattern 115. The reflected pattern includes an illuminated spot corresponding to each reflective surface 118 and a non-illuminated spot corresponding to each non-reflective surface 119. The reflected pattern is representative of a binary number, where each illuminated spot is representative of a one and each non-illuminated spot is representative of a zero.

Each of the light receivers 140 receives the reflected light from one of the discrete surfaces 117 and transmits an electrical signal to a processor 150 on the compute tray 125. The electrical signal transmitted from each light receiver 140 is indicative of a one corresponding to receipt of an illuminated spot and indicative of a zero corresponding to receipt of a non-illuminated spot. The processor 150 receives the multiple electrical signals from the multiple light receivers 140. The processor 150 decodes the multiple electrical signals to produce a binary number.

The decoded binary number has as many bits as there are discrete surfaces 117. In an embodiment, there are five discrete surfaces 117 and the binary number has five bits. In other embodiments, there can be more or less than five discrete surfaces 117 to accommodate a server rack 105 that has more than or less than 32 insertion slots 110. The processor 150 also converts the binary number to a decimal number and assigns the decimal number as the slot identifier 120.

In an embodiment, the computing system 100 further includes a rack management controller 155 communicatively coupled with the processor 150. A network management controller 160 is also communicatively coupled with the processor 150. In an embodiment, the processor 150 on the compute tray 125 automatically reports its detected slot identifier to the rack management controller 155 or other management software through a communication interface such as controller area network (CAN) bus or SMBus®. In an embodiment, the processor 150 is configured to communicate the slot identifier 120 to the rack management controller 155 and to the network management controller 160.

In an embodiment, the rack management controller 155 and the network management controller 160 are both housed in the server rack 105. In other embodiments, one or both of the rack management controller 155 and the network management controller 160 is housed outside of the server rack 105. The processor 150 communicates with the rack management controller 155 via a first communication interface bus 165. The processor 150 communicates with the network management controller 160 via a second communication interface bus 170.

The light transmitter 135 of each of the photosensor modules 130 continues to transmit the emitted light 137 toward the surface pattern 115 as long as the compute tray 125 remains inserted in an insertion slot 110. The rack management controller 155 dynamically updates the inventory of compute trays 125 that are inserted into the insertion slots 110 of the server rack 105. The rack management controller also dynamically updates the operational mapping of the compute trays 125 by associating each inserted compute tray 125 with a slot identifier 120 for the server rack 105. To do these dynamic updates, whenever a compute tray 125 is inserted into the server rack 105, the rack management controller 155 receives the slot identifier 120 for the compute tray 125 just inserted. Upon receiving the slot identifier 120, the rack management controller 155 updates the inventory and operational mapping for the server rack 105 to include the compute tray 125 just inserted.

Removal of a compute tray 125 from the server rack 105, will cause the processor 150 on the compute tray 125 to stop communicating the slot identifier 120 to the rack management controller 155. This loss of communication of the slot identifier 120 will cause the rack management controller 155 to dynamically update the inventory and operational mapping for the server rack 105 to exclude the just removed compute tray 125.

A computing system 100 that automatically detects and manages the slot identifier 120 for the insertion slot 110 that a compute tray 125 is inserted into is described herein. The compute tray 125 includes the multiple photosensor modules 130. Each of the photosensor modules 130 includes a light transmitter 135 and a corresponding light receiver 140. Each insertion slot 110 in the server rack 105 has a surface pattern 115 on an inside surface of the insertion slot 110. Each surface pattern 115 has multiple discrete surfaces 117, and is associated with a slot identifier 120.

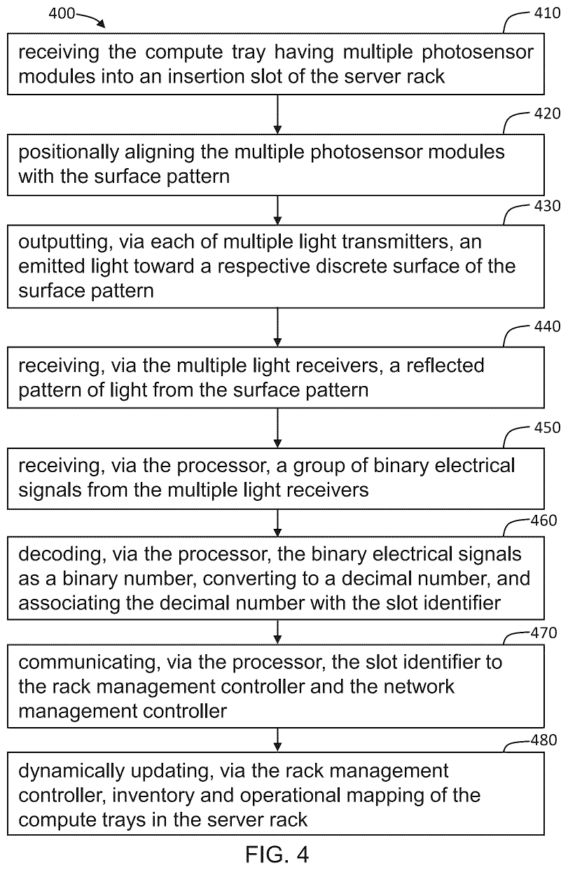

Referring to FIGS. 1 and 4, a method 400 for automatically detecting and managing the slot identifiers 120 begins at step 410. At step 410, the compute tray 125 having the multiple photosensor modules 130 is received into an insertion slot 110 of the server rack 105. At step 420, the multiple photosensor modules 130 are positionally aligned with the surface pattern 115. The positional alignment occurs as a result of receiving the compute tray 125 into the insertion slot 110.

At step 430, each of the multiple light transmitters 135 outputs an emitted light 137 toward a respective discrete surface 117 of the surface pattern 115. At step 440, the multiple light receivers 140 collectively receive a reflected pattern of light from the surface pattern 115. As part of the reflected pattern, each of the multiple light receivers 140 receives a reflected light 142 from a respective discrete surface 117 of the surface pattern 115. If one or more of the discrete surfaces 117 is a non-reflecting surface 119, then the reflected light 142 from the non-reflecting surface 119 will have a brightness that is below a threshold for receipt. This means that the reflected light 142 from the non-reflecting surface 119 will be received by the light receiver 140 as a non-illuminated spot.

At step 450, the processor 150 receives a group of binary electrical signals from the multiple light receivers 140. Each electrical signal is indicative of a one or a zero depending on whether the light receiver has received an illuminated or a non-illuminated spot. At step 460, the processor 150 decodes the binary electrical signals as a binary number. The processor 150 further converts the binary number to a decimal number, and associates the decimal number with the slot identifier 120.

In an embodiment, the light transmitter 135 of each of the photosensor modules 130 continues to transmit the emitted light 137 toward the surface pattern 115 as long as the compute tray 125 remains inserted in an insertion slot 110. The method 400 continues at step 470, where the processor 150 communicates the slot identifier 120 to the rack management controller 155 and to the network management controller 160. As noted above, the processor 150 communicates with the rack management controller 155 and the network management controller 160 via separate communication interface buses 165 and 170, respectively. At step 480, the rack management controller 155 dynamically updates the inventory and operational mapping of the compute trays 125 to include the compute tray 125 just inserted into the insertion slot 110 of the server rack 105. The dynamic update is based at least in part on receipt of the communication of the slot identifier 120 from the processor 150. If the compute tray 125 is removed from the server rack 105, the rack management controller 155 dynamically updates inventory and operational mapping of the compute trays 125 to exclude the compute tray 125 just removed from the insertion slot 110 of the server rack 105.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system for identifying a slot in a server rack, the computing system comprising:
a server rack having an insertion slot with a surface pattern, the insertion slot being associated with a slot identifier, the surface pattern having a plurality of discrete surfaces;
a compute tray insertable into the insertion slot, the compute tray including a first plurality of light transmitters and a respective second plurality of light receivers;
each of the first plurality of light transmitters outputting emitted light toward a respective discrete surface of the surface pattern, the emitted light being outputted upon insertion of the compute tray into the insertion slot;
each of the respective second plurality of light receivers detecting, based on the emitted light, reflected light from the respective discrete surface of the surface pattern; and
a processor communicatively coupled with the respective second plurality of light receivers and configured to:
receive, from the respective second plurality of light receivers, a respective plurality of signals indicative of the reflected light, and
determine the slot identifier based on the respective plurality of signals.

2. The computing system of claim 1, wherein each of the plurality of discrete surfaces is a reflective surface or a non-reflective surface.

3. The computing system of claim 2, wherein the reflected light from the discrete surfaces of the surface pattern includes a reflected pattern that corresponds to the surface pattern, the reflected pattern including an illuminated spot corresponding to each reflective surface and a non-illuminated spot corresponding to each non-reflective surface.

4. The computing system of claim 3, wherein the reflected pattern is representative of a binary number, the respective plurality of signals including a one for each illuminated spot and a zero for each non-illuminated spot.

5. The computing system of claim 4, wherein the binary number is a five-bit binary number.

6. The computing system of claim 4, further comprising:
a rack management controller communicatively coupled with the processor; and
a network management controller communicatively coupled with the processor;
wherein the processor is further configured to:
decode the binary number from the reflected pattern;
convert the binary number to a decimal number;
assign the decimal value to be the slot identifier; and
communicate the slot identifier to the rack management controller and the network management controller.

7. The computing system of claim 1, wherein the server rack has a plurality of insertion slots, each of the plurality of insertion slots being associated with a respective slot identifier, the slot identifier for each of the plurality of insertion slots being unique within the server rack.

8. A computing system for identifying a slot in a server rack, the computing system comprising:
a server rack having a plurality of insertion slots, each slot of the plurality of insertion slots having a surface pattern, the surface pattern having a plurality of discrete surfaces;
a compute tray configured for insertion into a respective slot of the plurality of insertion slots, the compute tray having a plurality of photosensor modules aligned, upon insertion of the compute tray in the respective insertion slot, with the surface pattern, each photosensor module including:
a light transmitter positioned to transmit, upon insertion of the compute tray in the respective slot, an emitted light toward a discrete surface of the surface pattern; and
a light receiver positioned to receive reflected light from the discrete surface of the surface pattern; and
a processor in communication with the plurality of photosensor modules, the processor being configured to:
receive from the plurality of photosensor modules a plurality of signals indicative of the reflected light, and
determine a slot identifier based on the plurality of signals.

9. The computing system of claim 8, wherein the surface pattern for each of the plurality of insertion slots is unique within the server rack.

10. The computing system of claim 8, wherein the light transmitter of each of the plurality of photosensor modules continues to transmit the emitted light toward the surface pattern as long as the compute tray remains inserted in the respective insertion slot.

11. The computing system of claim 8, wherein the surface pattern includes one or more reflective surfaces or non-reflective surfaces, each of the one or more reflective surfaces including a reflective film applied to a surface of the insertion slot, each of the one or more non-reflective surfaces including an absorptive film applied to the surface of the insertion slot.

12. The computing system of claim 8, wherein the emitted light has a wavelength in a range between about 900 nanometers and about 980 nanometers.

13. The computing system of claim 8, further comprising:
a rack management controller communicatively coupled with the processor; and
a network management controller communicatively coupled with the processor;
wherein the processor is further configured to:
decode the plurality of signals indicative of the reflected light to be a binary pattern representative of a binary number;
convert the binary number to a decimal number;
assign the decimal value to be the slot identifier; and
communicate the slot identifier to the rack management controller and the network management controller.

14. A method for automatic slot identifier detection and management of a compute tray in a rack system, the method comprising:
receiving a compute tray into an insertion slot of the server rack, the compute tray having a first plurality of light transmitters and a respective second plurality of light receivers, the insertion slot having a surface pattern and being associated with a slot identifier, the surface pattern having a plurality of discrete surfaces;
upon receiving the compute tray into the insertion slot, outputting an emitted light from each of the first plurality of light transmitters toward a respective discrete surface of the surface pattern;
receiving, via each of the second plurality of light receivers on the compute tray, a reflected light from the respective discrete surface of the surface pattern;
receiving, at a processor communicatively coupled with the second plurality of light receivers, a respective plurality of signals indicative of the reflected light; and
determining, via the processor and the respective plurality of signals, the slot identifier.

15. The method of claim 14, wherein each of the plurality of discrete surfaces is a reflective surface or a non-reflective surface, the reflected light from the discrete surfaces of the surface pattern including a reflected pattern that corresponds to the surface pattern, the reflected pattern including an illuminated spot corresponding to each reflective surface and a non-illuminated spot corresponding to each non-reflective surface.

16. The method of claim 15, wherein the surface pattern has at least five surfaces.

17. The method of claim 15, wherein the reflected pattern is representative of a binary number, the respective plurality of signals including a one for each illuminated spot and a zero for each non-illuminated spot.

18. The method of claim 17, further comprising:
decoding, via the processor, the binary number from the plurality of signals;
converting, via the processor, the binary number to a decimal number;
assigning, via the processor, the decimal number to be the slot identifier; and
communicating the slot identifier to a rack management controller and a network management controller.

19. The method of claim 14, wherein each of the first plurality of light transmitters continues outputting the emitted light from the transmitter as long as the compute tray remains inserted in the respective insertion slot.

20. The method of claim 14, wherein the emitted light has a wavelength in a range between about 900 nanometers and about 980 nanometers.
